(19) United States
(12) Patent Application Publication
(10) Pub. No.: US 2015/0122799 A1
(43) Pub. Date: May 7, 2015

(54) HEAT GENERATING DEVICE

(71) Applicant: DENSO CORPORATION, Kariya-city, Aichi-pref. (JP)

(72) Inventors: Toshihisa Taniguchi, Handa-shi (JP); Yoshihiko Shiraishi, Nagoya (JP); Atusi Sakaida, Nagoya (JP); Keiji Okamoto, Kariya-shi (JP); Keita Saitou, Chita-gun (JP)

(21) Appl. No.: 14/404,888

(22) PCT Filed: Apr. 26, 2013
(86) PCT No.: PCT/JP2013/062436

§ 371 Date: Dec. 1, 2014

(30) Foreign Application Priority Data
May 30, 2012 (JP) 2012-122823
Feb. 15, 2013 (JP) 2013-027279

(51) Int. Cl. H05B 3/12; H05B 3/26; H05K 3/00; H05B 3/18

(52) U.S. Cl. CPC H05B 3/12; H05B 3/18; H05B 3/267; H05K 3/0064; H05K 3/0044
USPC 219/539; 29/611

(57) ABSTRACT

To provide a heat generating device which is capable of minimizing the application of a large amount of heat through a contact with the heat generating device. The heat generating device includes an insulating base which contains a thermoplastic resin and has a front surface and a reverse surface and in which a plurality of via holes are formed to extend through a thickness, and heating resistors which are disposed in the via holes and generated heat when energized. Some of the heating resistors are connected in parallel.

### TECHNICAL FIELD

The invention relates to a heat generating device equipped with heating resistors which generate heat when energized.

### BACKGROUND ART

For instance, Japanese Patent First Publication No. 9-63755 proposes a heat generating device equipped with a plurality of heating resistors between two rubber sheets. Such a heat generating device works to generate heat by electrically energizing the heating resistors to heat surfaces of the rubber sheets to a given temperature and is used.

However, the above heat generating device has the heating resistors made of a single piece of wire. In other words, a heating part is arranged continuously, thus resulting in an increase in heat mass (i.e., heat capacity).

The above heat generating device is mounted on, for example, a lower surface of a steering column in a passenger compartment of a vehicle and used as a heater to warm feet of an occupant of the vehicle through radiation of heat. The limbs of the occupant may contact the heat generating device, thus resulting in application of a great deal of heat to the occupant through the contact, which may cause the occupant to be burned in the case where the heat mass of the heating resistors is great.

It is an object of the invention to provide a heat generating deice which is capable of minimizing the application of a great deal of heat through a contact with the heat generating device.

### SUMMARY OF THE INVENTION

In order to achieve the above object, the invention, as recited in claim 1, is characterized in that it includes an insulating base (10) which is made to contain a thermoplastic resin and has a front surface (10a) and a reverse surface (10b) opposite the front surface (10a), and in which a plurality of via holes (11) are formed to extend through a thickness, and heating resistors (4) which are disposed in the via holes, respectively, and generate heat when being electrically energized, and in that at least two or more of the heating resistors is connected in parallel.

With the above arrangements, the parallel connection of the at least two of the heating resistors results in a decrease in heat mass of each of the heating resistors. The arrangement of the heating resistors at an interval away from each other in the insulating base containing a thermoplastic resin serves to avoid the transfer of heat in a planar direction, thus minimizing the application of a large amount of heat to limbs of a person through a contact with the heat generating device.

Symbols in brackets for means, as described in the above column and claims, represent relationships with specific means as referred to in embodiments discussed later.

### BRIEF EXPLANATION OF DRAWINGS

FIG. 1 is a plane view of a front surface side of a heat generating device in the first embodiment of the invention;

FIG. 2 is a plane view of a reverse surface side of the heat generating device of FIG. 1;

FIG. 3 is a sectional view, as taken along the line in FIGS. 1 and 2;

FIG. 4 is a sectional view showing production processes of the heat generating device, as illustrated in FIG. 1;

FIG. 5 is a view which illustrates a case of use of the heat generating device of FIG. 1;

FIG. 6(a) is a schematic view showing the amount of heat to be applied from a contact area of a conventional heat generating device;

FIG. 6(b) is a schematic view showing the amount of heat to be applied from a contact area of the heat generating device illustrated in FIG. 1;

FIG. 7 is a plane view of a heat generating device according to the second embodiment of the invention;

FIG. 8 is a sectional view, as taken along the line VIII-VIII in FIG. 7; and

FIG. 9 is a sectional view, as taken along the line IX-IX in FIG. 7.

### EMBODIMENT FOR CARRYING OUT THE INVENTION

### First Embodiment

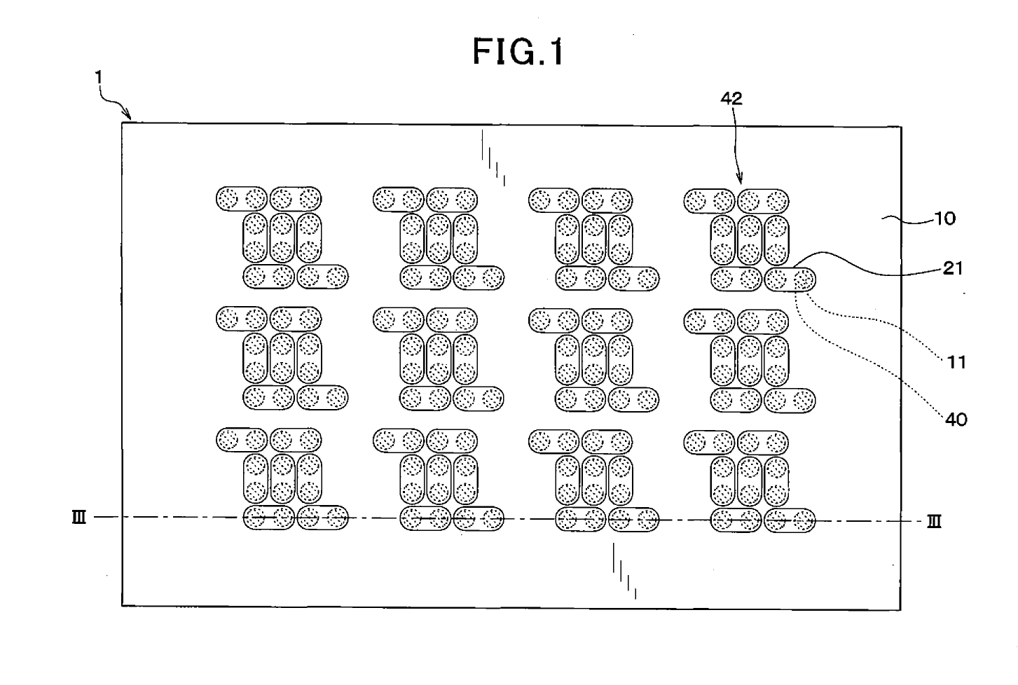

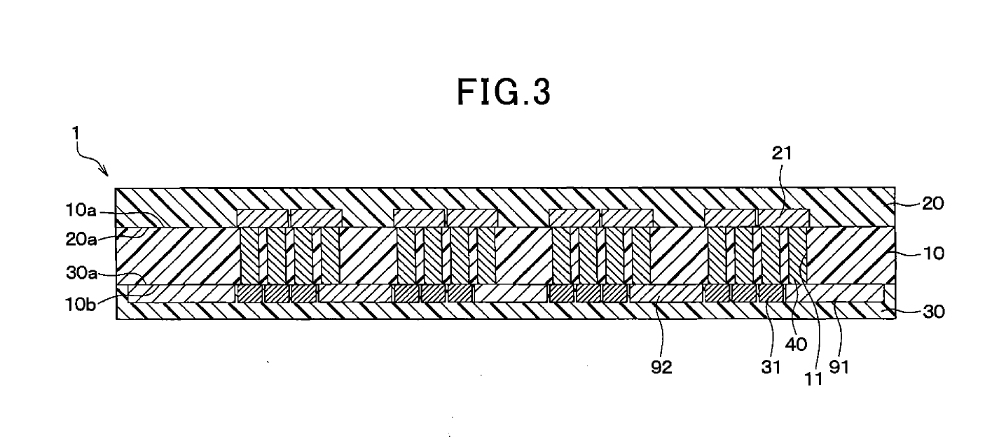

The first embodiment of the invention will be described below with reference to drawings. The heat generating device 1 of this embodiment is, as illustrated in FIGS. 1 to 3, made by unifying an insulating base 10, a front side protective member 20, and a reverse side protective layer 30 and arranging heating resistors 40 inside that unit.

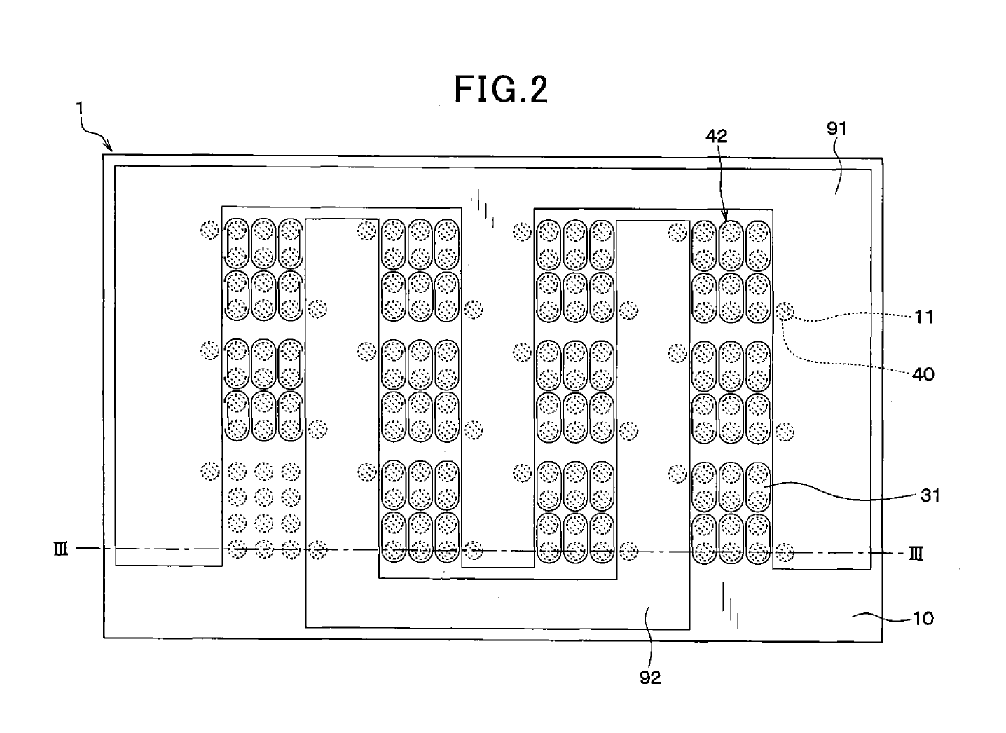

FIG. 1 omits the front side protective member 20 for the ease of understanding. FIG. 2 omits the reverse side protective member 20 for the ease of understanding. FIGS. 1 and 2 are not sectional views, but hatch the heating resistors 40.

In this embodiment, the insulating base 10 is formed by a rectangular planar thermoplastic resin film containing polyether ether ketone (PEEK) and polyetherimide (PEI). The insulating base 10 has a plurality of via holes 11 extending through a thickness thereof.

The insulating base 10 has the 168 via holes 11 which are broken down into a plurality of groups each made up of fourteen of the via holes 11. The via holes 11 are cylindrical to have a diameter constant from the front surface 10a to the reverse surface 10b, but may alternatively be of a tapered shape in which the diameter decreases from the front surface 10a to the reverse surface 10b or a rectangular cylindrical shape.

In each of the via holes 11, one of the heating resistors 40 is disposed. In other words, the insulating base 10 occupies among the heating resistors 40, so that all the heating resistors 40 are isolated by the insulating base 10. Although not limited, the heating resistors 40 are made by sintering a conductive paste containing particles of metal such as Ni—Sn.

On the front surface 10a of the insulating base 10, the front side protective member 20 is disposed which is made of a rectangular planar thermoplastic resin film containing polyether ether ketone (PEEK) and polyetherimide (PEI). The front side protective member 20 is identical in planar configuration with the insulating base 10 and has a plurality of patterned front side layers 21 formed in a surface 20a thereof facing the insulating base 10. Each of the front side layers 21 electrically connects adjacent two of the heating resistors 40.

On the reverse surface 10b of the insulating base 10, the reverse side protective member 30 is disposed which is made of a rectangular planar thermoplastic resin film containing polyether ether ketone (PEEK) and polyetherimide (PEI). The reverse side protective member 30 is identical in planar configuration with the insulating base 10 and has a plurality of patterned reverse side layers 31 formed on a surface 30a thereof facing the insulating base 10. Each of the reverse side layers 31 electrically connects two of the heating resistors 40 which are coupled to adjacent two of the front side layers 21, respectively.

A plurality of heating resistor groups 42 are provided each of which is made up of some of the heating resistors 40 which are connected in series through the front side layers 21 and the reverse side layers 31. In this embodiments, the twelve heating resistor groups 42 are formed each of which has fourteen of the heating resistors 40 which are coupled together in series. Some of the heating resistors 40 which are located on the edge of the heating resistor groups 42 are not joined to the reverse side layers 31.

On the reverse side protective member 30, a first feeding portion 91 and a second feeding portion 92 are formed. The first feeding portion 91 connects with the heating resistors 40 located on the edge of each of the heating resistor groups 42. The second feeding portion 92 connects with the heating resistors 40 located on the other edge of each of the heating resistor groups 42. The heating resistor groups 42 are connected in parallel through the first and second feeding portions 91 and 92.

On the reverse side protective member 30, layer-to-layer connecting members, not shown, are formed which are electrically connected to the first and second feeding portions 91 and 92 and exposed outside the surface of the reverse side protective member 30 which is farther away from the insulating base 10. The first and second feeding portions 91 and 92 are electrically connected to an external through the layer-to-layer connecting members.

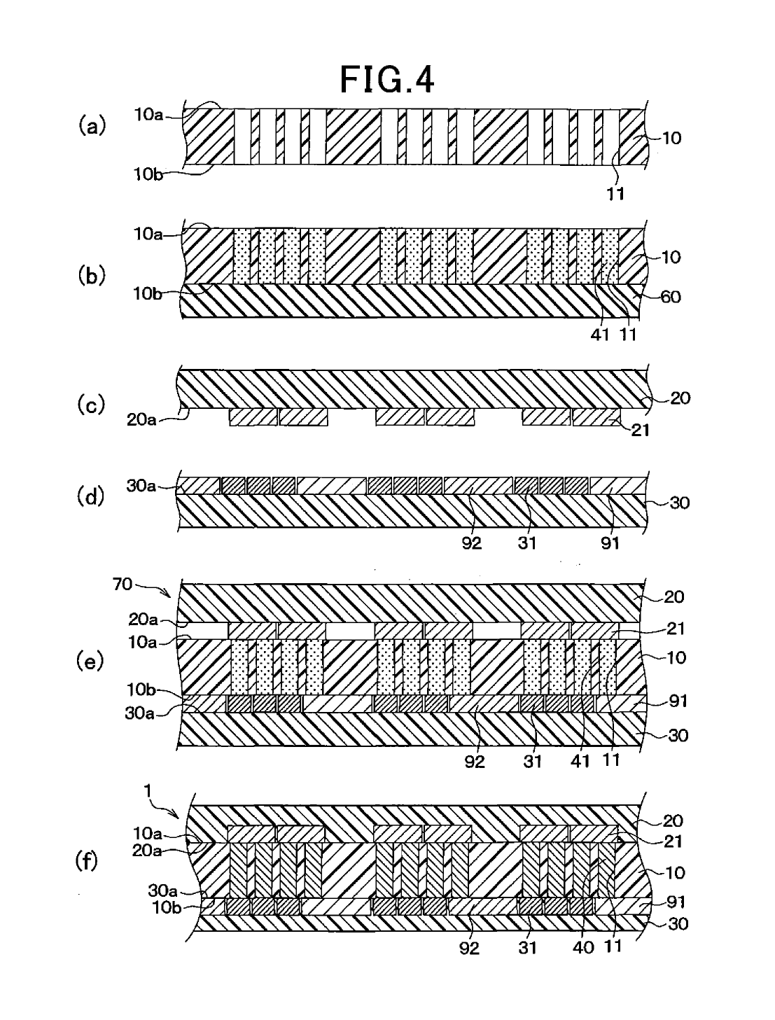

The heat generating device 1 has the above described structure. Next, a production method of the heat generating device 1 will be described below with reference to FIGS. 4(a) to 4(f). FIGS. 4(a) to 4(f) are sectional views, as taken along the line in FIG. 1.

First, the insulating base 10 is, as illustrated in FIG. 4(a), prepared. The plurality of via holes 11 are drilled.

Next, each of the via holes 11 is filled with the conductive paste 41. The conductive paste 41 is made by adding organic solvent, such as paraffin, to particles of Ni—Sn-based metal in paste form.

The method (or machine) for filling the via holes 11 with the conductive pates 41 may be achieved by one, as taught in Japanese Patent Application No. 2010-50356 filed by the same applicant as that of this application.

In short, the insulating base 10 is placed on a holding table, not shown, through absorbent paper 60 with the reverse surface 10a facing the adsorbent paper 60. The adsorbent paper 60 may be made of material capable of adsorbing the organic solvent of the conductive paste 41 and is common high-quality paper. The conductive paste 41 is melted and loaded into the via holes 11. This causes the organic solvent of the conductive paste 41 to be collected by the adsorbent paper 60, so that the metallic particles are arranged in close contact with each other in the via holes 11. In this way, the insulating base 10 filled with the conductive pates 41 is prepared.

In a process other than the above ones, copper foils are, as illustrated in FIGS. 4(c) and 4(d), formed on the surfaces 20a and 30a of the front side protective member 20 and the reverse side protective member 30 which face the insulating base 10. The copper foils are then subjected to patterning. This makes the front side protective member 20 on which the front side layers 21 are formed, and the reverse side protective member 30 on which the reverse side layers 31 and the first and second feeding portions 91 and 92 are formed.

Afterward, the reverse side protective member 30, the insulating base 10, and the front side protective member 20 are, as illustrated in FIG. 4(e), stacked in sequence to make a laminated body 70. Specifically, the front side protective member 20 is disposed on a side of the front surface 10a of the insulating base 10 with the respective conductive pastes 41 being in contact with the given front side layers 21. The reverse side protective member 30 is disposed on a side of the reverse surface 10b of the insulating base 10 with the respective conductive pastes 41 being in contact with the given reverse side layers 31 or the first and second feeding portions 91 and 92.

Subsequently, the laminated body 70 is, as illustrated in FIG. 4(f), interposed between two press plates, not shown. The upper and lower surfaces of the laminated body 70 are then pressed from the stacking direction while the laminated body 70 is being heated in a vacuum, so that the laminated body 70 is unified, and the conductive pastes 41 are burned to make the heating resistors 40. This produces the heat generating device 1.

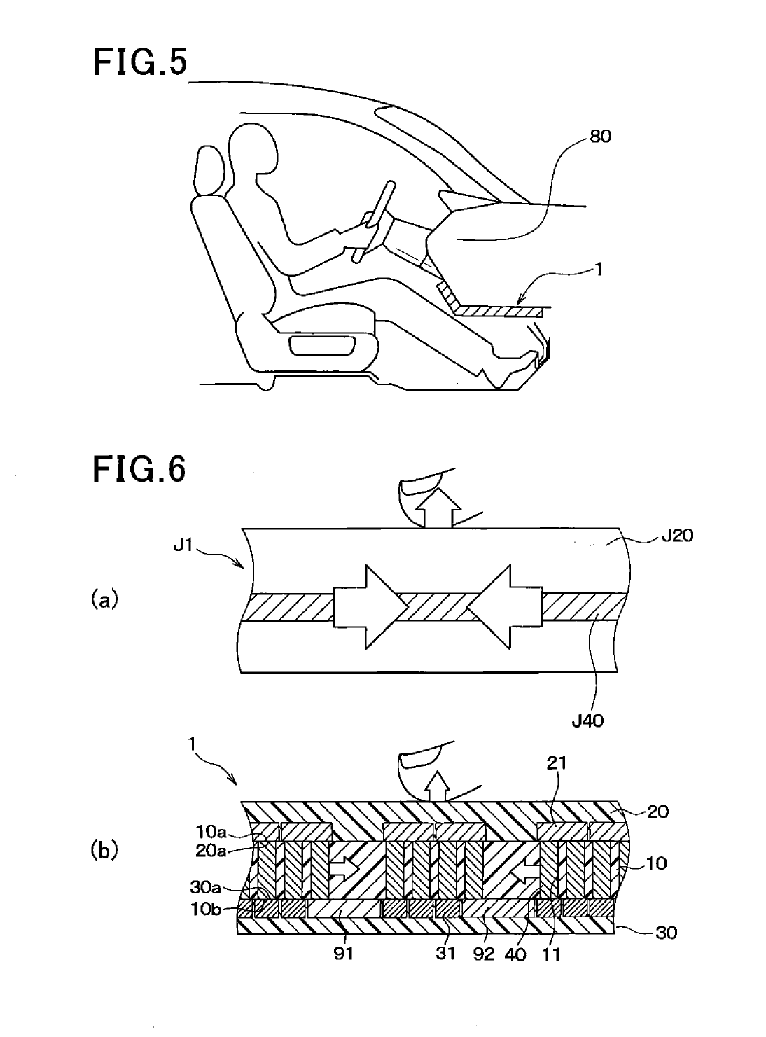

The heat generating device 1 is, as illustrated in FIG. 5, arranged outside an instrument panel 80 in which vehicle instruments are mounted in the front of the passenger compartment of the vehicle, more specifically, on a lower surface of the steering column for warming feet of an occupant of the vehicle quickly.

Specifically, the vehicle is usually equipped with a heating system whose thermal source is engine cooling water and which works to warm up the passenger compartment. When the engine is started, it is impossible to use the engine cooling water as a thermal source required to warm up the passenger compartment. It is, thus, difficult to warm up the passenger compartment. The quick warming up of the feet of the occupant of the vehicle is, therefore, achieved by operating the heat generating device 1.

The insulating base 10, the front side protective member 20, and the reverse side protective member 30 are made of resin and thus, as illustrated in FIG. 5, may be bent and disposed along the lower surface of the steering column. Although not illustrated, the heat generating device 1 may alternatively be installed on a lower portion of a door body (i.e., below a window) of either of the right or the left door of the vehicle.

The heat generating device 1 of this embodiment, as described above, has the plurality of heating resistor groups 42 connected in parallel by the first and second feeding portions 91 and 92. In other words, at least two of the heating resistors 40 are connected in parallel. This results in a decrease in heat mass of one of the heating resistor groups 42 (i.e., the heating resistors 40), thus avoiding the application of a large amount of heat to the occupant of the vehicle through a contact with the heat generating device 1 and minimizes the possibility of burn injury of the occupant in case of use of the heat generating device 1, like in FIG. 5.

The plurality of heating resistors 40 are arranged at an interval away from each other in the insulating base 10. In other words, the insulating base 10 occupies between each of the heating resistors 40, thereby avoiding the transfer of heat in a planar direction (i.e., a surface direction of the insulating base 10). This also minimizes the transfer of heat from some of the heating resistors 40 which are away from the contact to some of the heating resistors 40 which are near the contact, thereby further minimizing the possibility of burn injury of the occupant of the vehicle.

The case where a finger of a person contacts the heat generating device 1 will be studied. In the case, as illustrated in FIG. 6(a), where a heating resistor J40 is in the form of a single piece (e.g., in the shape of wire), the heat mass of the heating resistor J40 is great. Since the heating resistor J40 is continuous in shape, it is easy for the heat of the heating resistor J40 to transfer. Therefore, when the finger of a person contacts the front side protective member J20, it may cause a large amount of heat to transfer from the contact, which leads to the burn injury.

In contrast to the above, this embodiment has the heating resistor groups 42 connected in parallel to decrease the heat mass of each of the heating resistor groups 42. The insulating base 10 is disposed between the heating resistors 40 to control the transfer of heat in the planar direction of the insulating base 10. This minimizes the application of a large amount of heat to the finger of the person through a contact with the front side protective member J20 and avoids the burn injury.

In case of use of the heat generating device 1, like in FIG. 5, it is possible to keep the surface of the front side protective member 20 which is farther away from the insulating base 10 at a temperature great enough to warm up the feet of the occupant of the vehicle and minimizes the possibility of burn injury of limbs of the occupant when contacting the heat generating device 1.

The heat generating device 1 has the heating resistors 40 disposed in the via holes 11, respectively. The ease of adjustment of a temperature distribution over the surface of the heat generating device 1 is, therefore, achieved by changing locations, the size, or the distribution of density of the via hole 11.

### Second Embodiment

The heat generating device 1 according to the second embodiment of the invention will be described below. The heat generating device 1 of this embodiment is different from the one of the first embodiment in that all the heating resistors 40 are connected in parallel. Other arrangements are identical, and explanation thereof in detail will be omitted here.

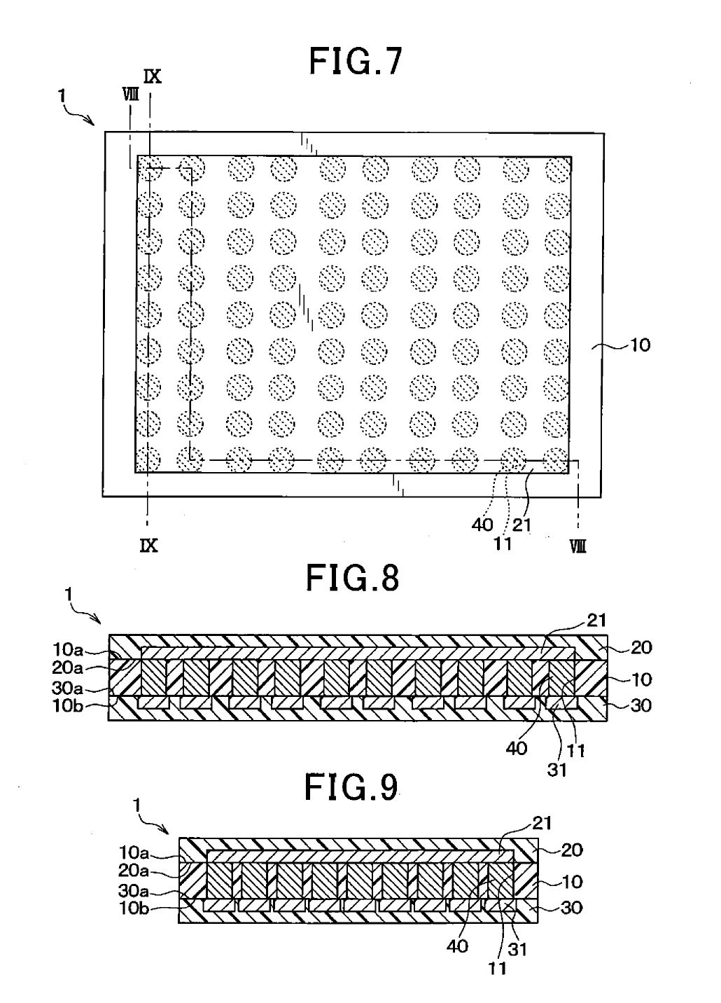

The front side protective member 20, as illustrated in FIGS. 7 to 9, has a single front side layer 21 formed on the surface 20a facing the insulating base 10. The front side layer 21 is electrically connected to all the healing resistors 40. In other words, the respective heating resistors 40 are electrically coupled with the same front side layer 21.

For the sake of ease of understanding, FIG. 7 omits the front side protective member 20. FIG. 7 is not a sectional view, but hatches the heating resistors 40. On the front side protective member 20, a layer-to-layer connecting member, not shown, is formed which is electrically connected to the front side layer 21 and exposed outside the surface of the front side protective member 20 which is farther away from the insulating base 10. The front side layer 21 is electrically connected to an external through the layer-to-layer connecting member.

The reverse side protective layer 30 has as many reverse side layers 31 as the heating resistors 40 formed on the surface 30a facing the insulating base 10. Each of the reverse side layers 31 is electrically connected to one of the heating resistors 40. In other words, the heat generating device 1 is engineered to have all the heating resistors 40 connected in parallel to the front side layer 21.

On the reverse side protective member 30, layer-to-layer connecting members, not shown, are formed which is electrically connected to the reverse side layers 31 and exposed outside the surface of the reverse side protective member 30 which is farther away from the insulating base 10. The reverse side layers 31 are electrically connected to an external through the layer-to-layer connecting members.

The heat generating device 1 is, as described above, designed to have the heating resistors 40 connected in parallel to the front side layer 21 and offers the same effects as those in the first embodiment.

The heat generating device 1 of this embodiment is capable of selectively activating the heating resistors 40. It is, therefore, possible to activate the heating resistors 40 so as to show characters, numbers, or symbols for use instead of Braille. In such a use, fingers of a person will contact the heat generating device 1, however, the heat generating device 1 is designed to minimize the possibility of application of a large amount of heat to the person through the contact. It is, thus, possible to minimize the possibility of burn injury while keeping the surface of the heat generating device 1 at a temperature high enough to make the person perceive the characters, etc.

### Modifications

The first embodiment is achieved by preparing the reverse side protective member 30 on which the reverse side layers 31 and the first and second feeding portions 91 and 92 are formed and then unifying the reverse side protective member 30, the insulating base 10, and the front side protective member 20, however the following modification may be made. The heat generating device 1 may be made by preparing the insulating base 10 which has the reverse side layers 31 and the first and second feeding portions 91 and 92 formed on the reverse surface 10b. In this case, the via holes 11 are formed in the step of FIG. 4(a) which have bottoms defined by the reverse side layers 31 or the first and second feeding portions 91 and 92. The via holes 11 are filled with the conductive pastes 41 without use of the adsorbent paper 60 in the step of FIG. 4(b). Similarly, the heat generating device 1 of the second embodiment may be made using the insulating base 10 which has the reverse side layers 31 formed on the reverse surface 10b.

The first embodiment may alternatively be achieved by stacking the reverse side protective member 30, the reverse side layers 31, the first and second feeding portions 91 and 92, the insulating base 10, the front side layers 21, and the front side protective member 20 in this order and unifying them. In other words, the front side protective member 20 and the front side layers 21, the reverse side protective member 30 and the reverse side layers 31, and the first and second feeding portions 91 and 92 may be separate from each other until the laminated body 70 is unified. Similarly, in the second embodiment, the front side protective member 20 and the front side layers 21, the front side protective member 20 and the front side layers 21, and the reverse side protective member 30 and the reverse side layers 31 may be separate from each other until the laminated body 70 is unified.

In the first embodiment, the configuration of the front side layers 21 and the reverse side layers 31 may be changed to arrange the first and second feeding portions 91 and 92 on the front surface 10a of the insulating base 10.

In the second embodiment, the single reverse side layer 31 may be formed on the surface 30a of the reverse side protective member 30 which faces the insulating base 10 to electrically connect the reverse side layer 31 to each of the heating resistors 40.

1. A heat generating device wherein it comprises an insulating base which is made to contain a thermoplastic resin and has a front surface and a reverse surface opposite the front surface, and in which a plurality of via holes are formed to extend through a thickness, and heating resistors which are disposed in the via holes, respectively, and generate heat when being electrically energized, and in that at least two of the heating resistors is connected in parallel, and said heating resistors are formed by sintering a conductive paste containing metallic particles.

2. A heat generating device as set forth in claim 1, wherein the insulating base has a plurality of front side layers disposed on the front surface thereof in connection with the given heating resistors, in that the insulating base has a plurality of reverse side layers disposed on the revere surface thereof in connection with the given heating resistors, in that the plurality of heating resistors are broken down into a plurality of heating resistor groups which are connected in series by said front side layers and the reverse side layers, and in that the plurality of heating resistor groups are connected to feeding portions disposed on the front surface or the reverse surface of said insulating base, so that the heating resistor groups are connected in parallel.

3. A heat generating device as set forth in claim 1, wherein a single front surface is disposed on a side of the front surface in electrical connection with all the heating resistors, in that a plurality of reverse side layers are disposed at an interval away from each other on a side of the reverse surface of the insulating base in electrical connection with all the heating resistors, and in that the plurality of heating resistors are connected in parallel by said front side layers and the reverse side layers.

4. A production method of a heat generating device comprising the steps of:
preparing an insulating base which is made to contain a thermoplastic resin and has a front surface and a reverse surface opposite the front surface;
forming a plurality of via holes which extend in a thickness-wise direction of the insulating base;
filling each of the via holes with a conductive paste containing metallic particles;
connecting at least two or more of the plurality of conductive pastes in the via holes in parallel; and
sintering each of the conductive pastes to make a heating resistor.

5. A production method of a heat generating device as set forth in claim 5, wherein the step of filling said conductive pates includes a step of preparing adsorbent paper, a step of arranging said insulating base with the reverse surface facing the adsorbent paper, and a step of filing said via holes with the conductive pates while melting said conductive pastes.

6. A production method of a heat generating device as set forth in claim 5, wherein it further comprises: the steps of
preparing a front side protective member and a reverse side protective member;
forming copper foils on surfaces and of said front side protective member and the reverse side protective member which face said insulating base;
patterning said cooper foils to form a front side pattern in the front side protective member and also form a reverse side pattern and a first and a second feeding portions in the reverse side protective member, respectively,
arranging the front side protective member on the front surface of the insulating base with the conductive pastes placed in contact with the front side pattern, and also arranging the reverse side protective member on the reverse surface of the insulating base with the conductive pastes placed in contact with the reverse side pattern and the first and second feeding portions to make a laminated body; and
sintering the conductive pastes in the laminated body to form heating resistors.
